(19) United States
(12) Patent Application Publication
(10) Pub. No.: US 2025/0287811 A1
(43) Pub. Date: Sep. 11, 2025

(54) DISPLAY DEVICE AND METHOD OF PROVIDING THE SAME

(71) Applicant: Samsung Display Co., Ltd., Yongin-si (KR)

(72) Inventors: JEONGSEOK LEE, Yongin-si (KR); HYOJEONG KWON, Yongin-si (KR); SOOYOUN KIM, Yongin-si (KR); Soomin OH, Yongin-si (KR); JINHO HYUN, Yongin-si (KR); Sangyeon HWANG, Yongin-si (KR); OHJUNE KWON, Yongin-si (KR)

(21) Appl. No.: 18/937,266

(22) Filed: Nov. 5, 2024

(30) Foreign Application Priority Data
Mar. 5, 2024 (KR) 10-2024-0031148

(51) Int. Cl. H10K 59/80; H10K 59/12; H10K 59/95

(52) U.S. Cl. CPC H10K 59/80; H10K 59/1201; H10K 59/95

(57) ABSTRACT

A display device includes an active region, a bendable region, and a pad region which is spaced apart from the active region along a direction with the bendable region therebetween and includes a driving chip and pads, and a lower member including a flat part which overlaps the active region and is in contact with the display panel at the first region, a protruding part which is on the flat part and adjacent to a boundary between the active and bendable regions, and a pad part which is disconnected from the flat part and the protruding part, overlaps the pad region and is in contact with the display panel at the pad region. The display panel which is bent at the bendable region includes the protruding part and the pad part in contact with each other.

This application claims priority to Korean Patent Application No. 10-2024-0031148, filed on Mar. 5, 2024, and all the benefits accruing therefrom under 35 U.S.C. § 119, the entire contents of which are hereby incorporated by reference.

### BACKGROUND

### (1) Field

The present disclosure herein relates to a display device and a method of manufacturing (or providing) the same. More particularly, the present disclosure herein relates to a display device with reduced cost and simplified process, and a method of manufacturing (or providing) the same.

### (2) Description of the Related Art

Various display devices used for multi-media devices, such as a television, a mobile phone, a tablet computer, a navigation system, and a game console, are being developed. A display panel which has a bendable portion to be accommodated in a housing, is being developed in order to reduce a dead space of the display device.

### SUMMARY

The present disclosure provides a method of manufacturing (or providing) a display device which enables to reduce the cost of a lower member disposed under a display panel having a bendable portion, and to simplify the process.

An embodiment of the invention provides a display device including a display panel having a first region having an active region in which pixels are disposed, a second region bendable with respect to a bending axis extending along a first direction, and a third region which is spaced apart from the first region along a second direction crossing the first direction with the second region therebetween and in which a driving chip and pads are disposed, and a lower member in contact with a rear surface of the display panel, wherein the lower member includes a flat part overlapping an entire surface of the first region and in contact with the rear surface, a protruding part disposed on the flat part and overlapping the first region adjacent to a boundary between the first region and the second region, and a pad part overlapping the third region and in contact with the rear surface, and when the second region is bent, the protruding part and the pad part are in contact with each other.

In an embodiment, the protruding part may expose a portion of an upper surface of the flat part.

In an embodiment, the flat part may have a first thickness, the protruding part may have a second thickness smaller than the first thickness, and the pad part may have a third thickness smaller than the second thickness.

In an embodiment, the first thickness may be about 100 micrometers (μm) to about 300 μm, the second thickness may be about 50 μm to about 200 μm, and the third thickness may be about 50 μm to about 150 μm.

In an embodiment, the flat part, the protruding part, and the pad part may include a polymer resin and carbon black.

In an embodiment, the flat part, the protruding part, and the pad part may further include at least one of graphite, copper (Cu), aluminum (Al), carbon nanotube (CNT) and graphene.

In an embodiment, the flat part and the protruding part may include a polymer resin and carbon black, and the pad part may include only the polymer resin.

In an embodiment, the lower member may have an optical density of about 3 to about 5.

In an embodiment, the lower member may have a thermal conductivity of about 20 watts per meter Kelvin (W/mk) to about 100 W/mk.

In an embodiment, the lower member may have a storage modulus of about 0.01 megapascal (MPa) to about 1 MPa.

In an embodiment, the display device may further include an input sensor directly disposed on the display panel.

In an embodiment, the display device may further include an optical film overlapping the first region and disposed on the display panel.

In an embodiment, the display device may further include a window disposed on the optical film.

In an embodiment, the display device may further include a bending cover layer overlapping the second region and covering an upper surface of the display panel.

In an embodiment, the display device may further include a flexible circuit film connected to the pads, and a portion of the flexible circuit film may be in contact with the flat part when the second region is bent.

In an embodiment, the display device may further include a conductive film which covers the flexible circuit film overlapping the driving chip and the pads.

In an embodiment of the invention, a manufacturing method of a display device includes providing a display panel having first to third regions sequentially arranged along one direction, forming a flat part on a rear surface of the display panel overlapping the first region, forming a protruding part on the flat part adjacent to a boundary between the first region and the second region, forming a pad part on the rear surface of the display panel overlapping the third region, and bending the second region with respect to a bending axis extending along an intersection direction crossing the one direction, and after the bending of the second region, the protruding part and the pad part are in contact with each other.

In an embodiment, the flat part, the protruding part, and the pad part may be formed by spraying ink onto the rear surface of the display panel using a nozzle through an inkjet process, and the ink may be ink in which a polymer resin contains carbon black.

In an embodiment, the material contained in the ink may have an optical density of about 3 to about 5, a thermal conductivity of about 20 W/mk to about 100 W/mk, and a storage modulus of about 0.01 MPa to about 1 MPa.

In an embodiment of the invention, a manufacturing method of a display device includes providing a display panel having first to third regions sequentially arranged along one direction, forming a flat part on a rear surface of the display panel overlapping the first region, forming a pad part on the rear surface of the display panel overlapping the third region, forming a protruding part on the pad part, and bending the second region with respect to a bending axis extending along an intersection direction crossing the one direction, and after the bending of the second region, the protruding part and the pad part are in contact with each other.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device according to an embodiment of the invention;

FIG. 2 is an exploded perspective view of a display device according to an embodiment of the invention;

FIG. 3 is a cross-sectional view taken along line I-I′ of FIG. 2;

FIG. 4A is a cross-sectional view of a display device illustrating a bent state of a display panel according to an embodiment of the invention;

FIG. 4B is a cross-sectional view of a display device illustrating a bent state of a display panel according to an embodiment of the invention;

FIG. 5 is a plan view of a display panel according to an embodiment of the invention;

FIG. 6 is a plan view of an input sensor according to an embodiment of the invention;

FIG. 7 is an enlarged cross-sectional view of a display module according to an embodiment of the invention;

FIGS. 8A to 8D are cross-sectional views illustrating structures in a method of manufacturing (or providing) a display device according to an embodiment of the invention; and

FIGS. 9A to 9C are cross-sectional views illustrating structures in a method of manufacturing (or providing) a display device according to an embodiment of the invention.

### DETAILED DESCRIPTION

In this specification, it will be understood that when an element (or a region, a layer, a portion, or the like) is referred to as being related to another element such as being “on”, “connected to” or “coupled to” another element, it may be directly disposed on, connected or coupled to the other element, or intervening elements may be disposed therebetween. In contrast, when an element (or a region, a layer, a portion, or the like) is referred to as being related to another element such as being “directly on”, “directly connected to” or “directly coupled to” another element, no intervening element is disposed therebetween.

Like reference numerals or symbols refer to like elements throughout. Within the Figures and the text of the disclosure, a reference number indicating a singular form of an element may also be used to reference a plurality of the singular element. In the drawings, the thickness, the ratio, and the size of the element are exaggerated for effective description of the technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section.

In addition, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the accompanying drawings.

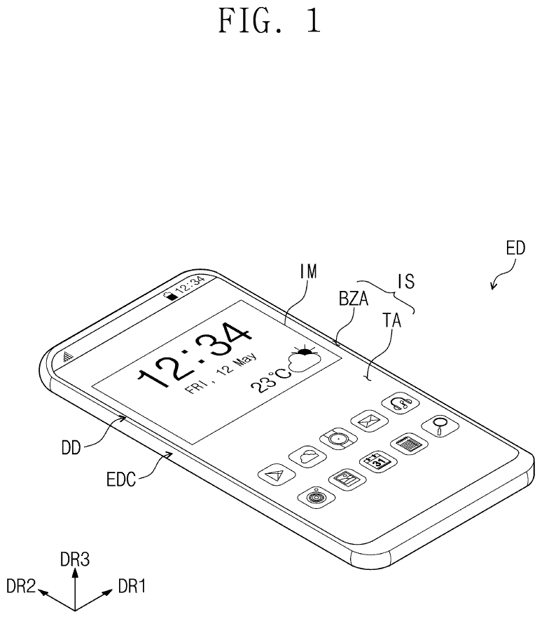

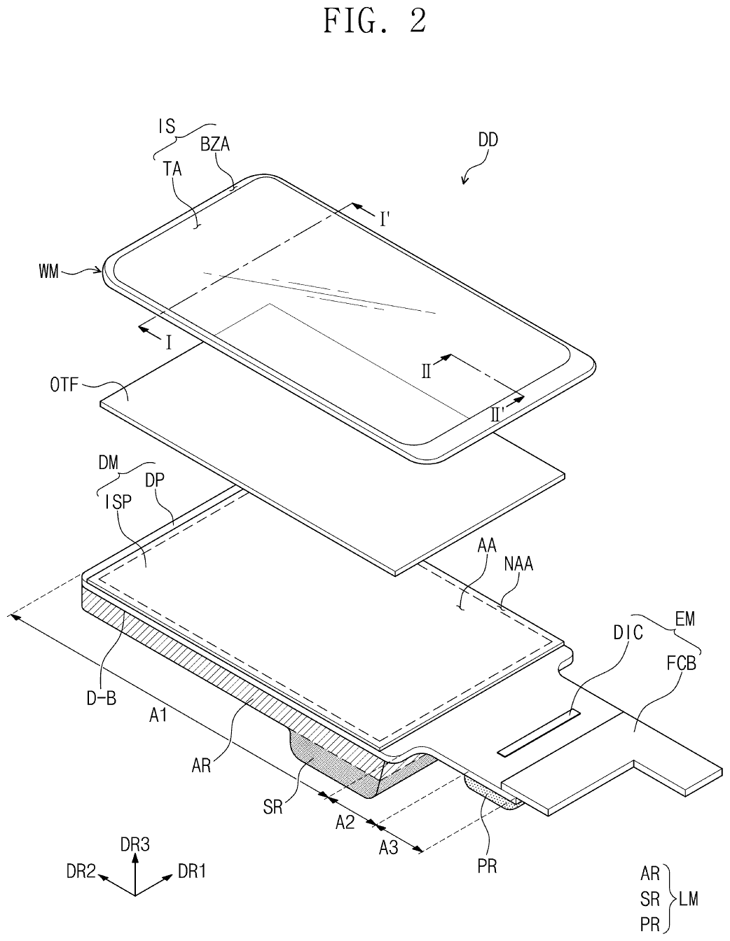

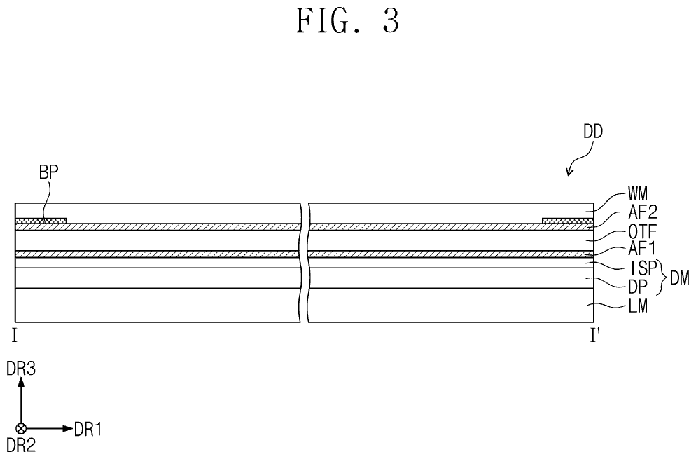

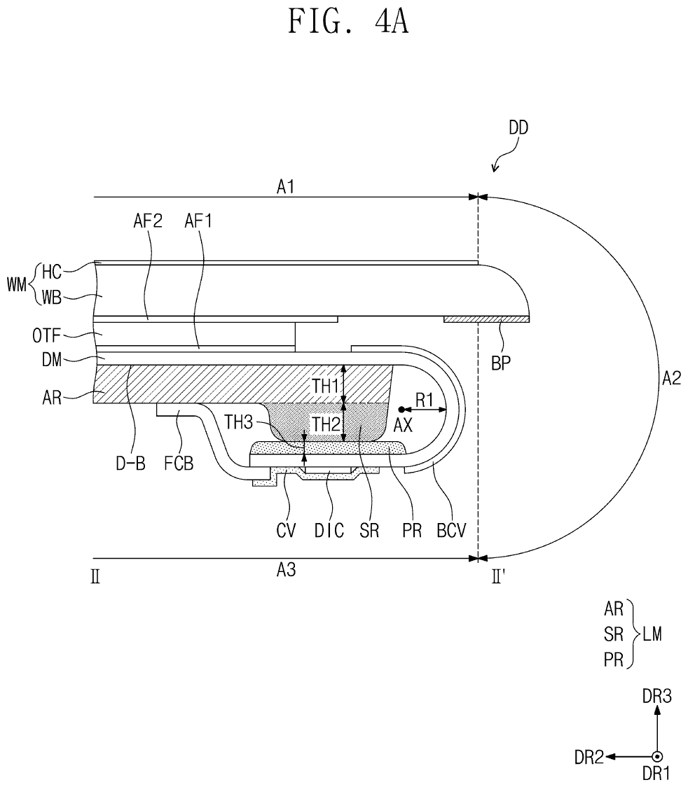

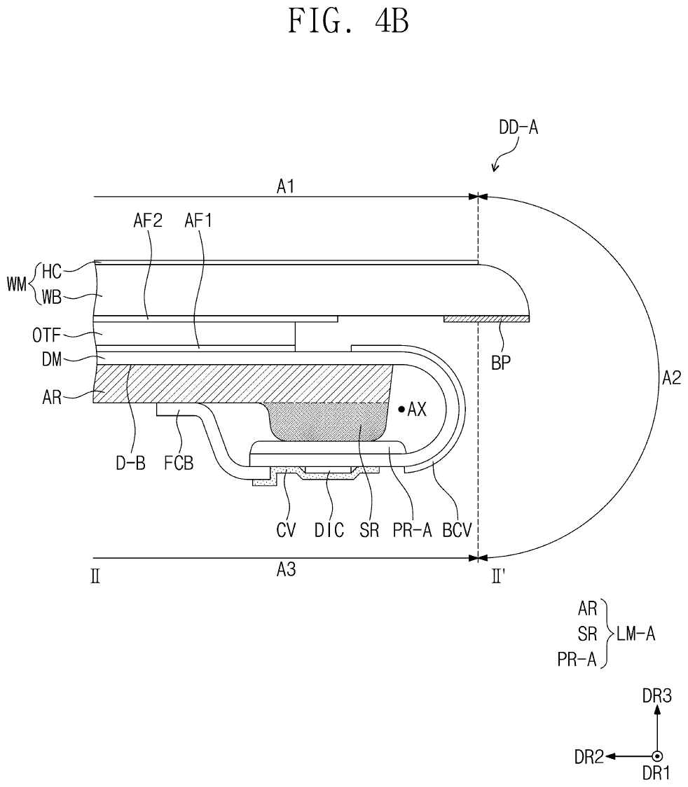

FIG. 1 is a perspective view of a display device as an electronic device ED according to an embodiment of the invention. FIG. 2 is an exploded perspective view of the display device DD according to an embodiment of the invention. FIG. 3 is a cross-sectional view taken along line I-I′ of FIG. 2. FIG. 4A is a cross-sectional view of a display device DD illustrating a bent state of a display panel DP according to an embodiment of the invention. FIG. 4B is a cross-sectional view of a display device DD illustrating a bent state of a display panel DP according to an embodiment of the invention.

Referring to FIGS. 1 to 3, an electronic device ED may be activated in response to electrical signals. The electronic device ED may include various embodiments. For example, the electronic device ED may be a display device DD such as a smart watch, a tablet computer, a laptop computer, a computer, and a smart television.

The electronic device ED may display an image IM toward a third direction DR3, on a display surface IS parallel to a plane defined by a first direction DR1 and a second direction DR2 which cross each other. The display surface IS on which the image IM is displayed may correspond to or define a front surface of the electronic device ED. The image IM may include a still image as well as a dynamic image.

In this embodiment, a front surface (or upper surface) and a rear surface (or lower surface) of each of members are defined on the basis of the third direction DR3 in which the image IM is displayed. The front surface and the rear surface may be opposed to each other in the third direction DR3, and the normal direction of each of the front surface and the rear surface may be parallel to the third direction DR3.

A distance between the front surface and the rear surface in the third direction DR3 may correspond to the thickness of the electronic device ED in the third direction DR3. A thickness of the electronic device ED and various components or layers thereof may be defined along the third direction DR3, that is, a thickness direction. Directions indicated by the first to third directions DR1, DR2, and DR3 are relative concepts and may thus be changed to other directions.

The electronic device ED may detect an external input applied from the outside. The external input may include various types of inputs provided from the outside of the electronic device ED. For example, the external input may include not only an external input applied by contact of an input tool like a part of a user's body such as a hand, but also an external input applied by an input tool in proximity to, or adjacent at a predetermined distance to the electronic device ED (for example, hovering). In addition, the external input may have various forms such as power, pressure, temperature, and light.

The display surface IS of the electronic device ED may be divided into a transmission region TA and a bezel region BZA. The transmission region TA may be a region where the image IM is displayed. A user outside of the electronic device ED views the image IM through the transmission region TA. In this embodiment, the transmission region TA is illustrated in a quadrilateral shape with rounded corners. However, this is exemplarily illustrated, the transmission region TA may have various planar shapes, and is not limited to any one embodiment of the invention.

The bezel region BZA is adjacent to the transmission region TA. The bezel region BZA may have a predetermined color. The bezel region BZA may surround the transmission region TA in the plan view (e.g., a view along the third direction DR3). Accordingly, the planar shape of the transmission region TA may be substantially defined by the bezel region BZA. A boundary may be defined between the transmission region TA and the bezel region BZA. However, this is exemplarily illustrated, and the bezel region BZA may also be disposed adjacent to only one side of the transmission region TA, and may also be omitted. The electronic device ED according to an embodiment of the invention may include various embodiments, and is not limited to any one embodiment of the invention.

The electronic device ED may include a display device DD and a housing EDC. As illustrated in FIG. 2, the display device DD may include a window WM, a display module DM, a driving module EM, an optical film OTF, and a lower member LM. The display module DM may include a display panel DP and an input sensor ISP which is disposed on the display panel DP. The display panel DP generates the image IM, and the input sensor ISP acquires coordinate information on the external input (for example, touch event).

The window WM may be made of (or include) a transparent material capable of transmitting images and/or light. For example, the window WM may be made of glass, sapphire, plastic, etc. The window WM is illustrated as a single layer, but an embodiment of the invention is not limited thereto, and the window WM may include a plurality of layers. Although not illustrated in the drawing, the bezel region BZA of the display device DD, previously described, may be provided as a region of the window WM which is substantially printed with a material having a predetermined color.

The display module DM may include the display panel DP and the input sensor ISP. The display panel DP, according to an embodiment of the invention, may be an emission-type display panel (e.g., a display panel DP which self-emits light), but an embodiment of the invention is not particularly limited thereto. For example, the display panel DP may be an organic light-emitting display panel, an inorganic light-emitting display panel, or a quantum-dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum-dot light-emitting display panel may include quantum dots, quantum rods, etc. Hereinafter, the display panel DP is described as the organic light-emitting display panel.

The input sensor ISP may be a layer which is ‘directly disposed’ on the display panel DP. According to an embodiment of the invention, the input sensor ISP may be formed (or provided) on the display panel DP through a continuous process. That is, when the input sensor ISP is directly disposed on the display panel DP, an adhesive film for bonding the input sensor ISP to the display panel DP is not disposed between the input sensor ISP and the display panel DP. In an embodiment, the input sensor layer may contact the display panel DP. As being in (physical) contact, elements or layers may form an interface therebetween.

The optical film OTF is a layer which decreases the reflectance for external light incident from an upper side of the window WM. The optical film OTF, according to an embodiment of the invention, may include a retarder and/or a polarizer. The retarder may be a film type or liquid crystal coating type, and may include a [symbol] retarder and/or a [symbol] retarder. The polarizer may also be a film type or a liquid crystal coating type. The film type may include a stretchable synthetic resin film, and the liquid crystal coating type may include liquid crystals arranged with a predetermined arrangement. The retarder and the polarizer may be provided as one polarizing film. The optical film OTF may further include a protection film disposed above or under the polarizing film.

The optical film OTF may be disposed on the input sensor ISP. That is, the optical film OTF may be disposed between the input sensor ISP and the window WM. The input sensor ISP, the optical film OTF, and the window WM may be bonded to each other through one or more adhesive layers respectively therebetween.

Referring to FIG. 3, a window adhesive layer AF1 is disposed between the input sensor ISP and the optical film OTF, and an optical adhesive layer AF2 is disposed between the optical film OTF and the window WM. Therefore, the optical film OTF is bonded to the input sensor ISP by the window adhesive layer AF1, and the window WM is bonded to the optical film OTF by the optical adhesive layer AF2.

As an example of the invention, the adhesive layers AF1 and AF2 may each include an optically clear adhesive film (OCA). However, the material of each of the adhesive layers AF1 and AF2 is not limited thereto, and may include a general adhesive or gluing agent. For example, the adhesive layers AF1 and AF2 may each include a pressure sensitive adhesive (PSA), an optical clear adhesive (OCA), or an optical clear resin (OCR).

In addition to the optical film OTF, a functional layer which performs another function, for example, a protection layer, etc., may further be disposed between the display module DM and the window WM.

The display module DM may display images in response to electrical signals, and may transmit/receive information as an external input. The display module DM may be defined as or divided into an active region AA and a peripheral region NAA. The active region AA may be defined as a planar area where an image IM provided from the display module DM is displayed (e.g., a display area). The peripheral region NAA may be defined as a planar area where an image IM is not displayed (e.g., a non-display area).

The peripheral region NAA is adjacent to the active region AA. For example, the peripheral region NAA may surround the active region AA in the plan view. However, this is exemplarily illustrated, the peripheral region NAA may be defined in various planar shapes, and is not limited to any one embodiment of the invention. According to an embodiment, the active region AA of the display module DM may correspond to at least a portion of the transmission region TA. That is, the active region AA of the display module DM may overlap a portion of the transmission region TA along the thickness direction.

As illustrated in FIG. 2, the display module DM may include the first region A1, the second region A2 and the third region A3 arranged along the second direction DR2. The first region A1 may include the active region AA and a portion of the peripheral region NAA, and the second region A2 and the third region A3 may together include the remaining portion of the peripheral region NAA other than the portion of the peripheral region NAA. The second region A2 may be a bending region bendable with respect to a bending axis, and the first region Al and the third region A3 may be non-bending regions. The third region A3 may be a pad region including a driving chip DIC and pads PD which are adjacent to the driving chip DIC.

Along the first direction DR1, the length of each of the second region A2 and the third region A3 in the first direction DR1 may be smaller than or equal to the length of the first region Al in the first direction DR1. A region with a short length along a direction of the bending axis may be bendable more easily.

The driving module EM may control operation of the display module DM. The driving module EM may include a flexible circuit film FCB and a driving chip DIC. The flexible circuit film FCB may be electrically connected to the display panel DP. The flexible circuit film FCB may be bonded to the display panel DP at an end portion of the third region A3 of the display module DM, such as through a bonding process. The flexible circuit film FCB may be electrically connected to the display module DM through an anisotropic conductive adhesive layer. The driving chip DIC may be mounted on the display panel DP at the third region A3 of the display module DM. The driving chip DIC may include driving circuits for driving pixels PX of the display panel DP which are in the active region AA, for example, data driving circuits.

According to an embodiment, the flexible circuit film FCB may include a ground line in order for discharging static electricity which would otherwise flow into the flexible circuit film FCB and/or into the input sensor ISP.

The driving module EM may further include a plurality of driving elements mounted on the flexible circuit film FCB. The plurality of driving elements may include a circuit part for converting (electrical) signals input from the outside into (electrical) signals necessary for the driving chip DIC, or into (electrical) signals necessary for driving the display module DM. When the second region A2 and the third region A3 of the display module DM are bent, the flexible circuit film FCB may be disposed under the display module DM. That is, the electronic device ED which is bent may include the flexible circuit film FCB facing the display module DM along the thickness direction.

The lower member LM is disposed on or facing a rear surface of the display module DM. The lower member LM may be disposed on the rear surface of the display module DM to improve impact resistance of the display device DD. According to an embodiment of the invention, the lower member LM may be directly disposed on a rear surface D-B of the display panel DP. That is, a separate adhesive layer may be omitted between the rear surface of the display panel DP and the lower member LM. Here, an interface may be defined between the lower member LM and the rear surface D-B of the display panel DP.

The lower member LM according to an embodiment of the invention may include a flat part AR, a protruding part SR, and a pad part PR.

The flat part AR may overlap an entirety of the first region A1. The flat part AR may be disposed under the display panel DP, and may be in contact with the rear surface D-B of the display panel DP.

The protruding part SR may overlap a planar area of the first region A1 which is adjacent to a boundary between the first region A1 and the second region A2. The protruding part SR may be disposed on the flat part AR. The protruding part SR may protrude from the flat part AR in the third direction DR3, in a direction opposite to the display panel DP. According to an embodiment, the protruding part SR may have a reversed trapezoidal shape on a cross section, such as a DR2-DR3 plane view. The flat part AR and the protruding part SR are substantially an integrated pattern, but are separately illustrated for the convenience of description.

The pad part PR may overlap the third region A3. The pad part PR may be in contact with the rear surface D-B of the display panel DP. The pad part PR may be spaced apart from the flat part AR and the protruding part SR along the second direction DR2. That is, a gap may be defined between the pad part PR and each of the flat part AR and the protruding part SR, respectively. Such gap may extend along the first and second directions DR1 and DR2.

The housing EDC may be coupled to the window WM to define the exterior of the electronic device ED. The housing EDC provides a receiving space which accommodates the display device DD. The housing EDC absorbs impact applied from the outside and prevents foreign substances/moisture from penetrating the electronic device ED from outside thereof to thereby protect the components accommodated in the housing EDC. As an example of the invention, the housing EDC may be provided in a form of a plurality of accommodating members being coupled to each other to form the overall structure of the housing EDC.

FIG. 4A is a cross-sectional view of a display device DD illustrating a bent state of a display panel DP according to an embodiment of the invention. FIG. 4A illustrates a cross section of the display device DD at an end portion thereof which is adjacent to a second region A2 in a state where the display device DD is bent at the second region A2 with respect to a bending axis AX extending along a first direction DR1.

The display device DD may include a window WM, an optical film OTF, a display module DM, and a lower member LM. The lower member LM may include a flat part AR, a protruding part SR, and a pad part PR. The lower member LM may be in contact with a rear surface D-B of the display panel DP.

The window WM according to an embodiment may include a base part WB, a hard-coating layer HC, and a bezel pattern BP. The base part WB may include an optically transparent insulating material. For example, the base part WB may include a glass substrate or a synthetic resin film. The hard-coating layer HC as an outer protection layer for protecting the base part WB may be disposed on any one among a front surface and a rear surface of the base part WB. The hard-coating layer HC may prevent damage to the base part WB due to scratches, etc. In addition, an anti-fingerprint layer may further be disposed on the base part WB. The outer protection layer may include the hard-coating layer HC and/or the anti-fingerprint layer as functional layers of the outer protection layer.

The bezel pattern BP defines the bezel region BZA (see FIG. 1) of the window WM. The bezel pattern BP may be disposed adjacent to an edge of the rear surface of the base part WB. Referring to FIG. 4A, the window WM may be separable from the display module DM at the second region A2.

The bezel pattern BP, which is a colored layer, may be formed (or provided) through coating a material in a method of providing the electronic device ED. As the material, the bezel pattern BP may include a polymer resin and a pigment which is combined with the polymer resin. The polymer resin may be, for example, an acrylate-based resin or polyester, and the pigment may be a carbon-based pigment.

The optical film OTF may be disposed under the window WM. The optical film OTF may decrease the reflectance for external light incident from the window WM. The window WM and the optical film OTF may be bonded to each other through a window adhesive layer AF1. The display module DM and the optical film OTF may be bonded to each other through an optical adhesive layer AF2.

The lower member LM, according to an embodiment of the invention, may serve as a functional layer which protects the display module DM. The functional protection layer provided by the lower member LM may have an electromagnetic-wave shielding function, a light-blocking function, a heat-dissipating function, and/or a cushioning function.

The lower member LM may have the light-blocking function since the components disposed in the active region AA of the display module DM are prevented from being seen through the window WM. The lower member LM may include a binder material and a plurality of pigment particles which are dispersed therein. The binder may include a polymer resin. The pigment particles may include carbon black, etc. The optical density of the lower member LM may be about 3 to about 5. An electronic device ED according to an embodiment may have light-shielding improvement effect by including a light-blocking layer.

The lower member LM may effectively dissipate heat generated from the display module DM. The lower member LM may include at least one of graphite, copper (Cu), aluminum (Al), carbon nanotube (CNT) and graphene, which has good heat-dissipation characteristics, and an embodiment of the invention is not limited thereto. The thermal conductivity of the lower member LM, according to an embodiment, may be about 20 watts per meter Kelvin (W/mk) to about 100 W/mk. Accordingly, the lower member LM may not only improve heat-dissipation characteristics, but also have electromagnetic-wave shielding or electromagnetic-wave absorbing characteristics.

The lower member LM may have the cushioning function. The lower member LM may include a matrix made of a flexible material. The matrix includes a synthetic resin. For example, the matrix may include at least one of a polymer resin, an acrylonitrile butadiene styrene copolymer (ABS), polyurethane (PU), polyethylene (PE), ethylene vinyl acetate (EVA) and polyvinyl chloride (PVC). According to an embodiment, the storage modulus of the lower member LM may be about 0.01 megapascal (MPa) to about 1 MPa.

In the state where the second region A2 of the display panel DP is bent, the protruding part SR and the pad part PR may be in contact with each other. According to an embodiment of the invention, when a distance (e.g., a minimum distance) from the bending axis AX to the second region A2 of the rear surface D-B of the display panel DP is defined as a radius of curvature R1, double the radius of curvature R1 may be equal to the total sum of a first thickness TH1 of the flat part AR, a second thickness TH2 of the protruding part SR, and a third thickness TH3 of the pad part PR.

According to an embodiment of the invention, the first thickness TH1 of the flat part AR may be about 100 micrometers (μm) or more and about 300 μm or less. The second thickness TH2 of the protruding part SR may be about 50 μm or more and about 200 μm or less. The third thickness TH3 of the pad part PR may be about 50 μm or more and about 150 μm or less.

The display panel DP according to an embodiment may further include a bending cover layer BCV disposed on the second region A2. The bending cover layer BCV may reduce stress applied to the second region A2 during the bending of the second region A2, and protect the second region A2. The bending cover layer BCV may include an organic material, or may be provided in the form of a tape, and is not limited to any one embodiment of the invention. The bending cover layer BCV may extend from the second region A2 to the first region A1, in a direction along the display module DM.

The display device DD according to an embodiment may further include a protection layer (not shown) filling an inner space defined by the bending of the second region A2. The protection layer may support the display module DM such that the form of the second region A2 may be maintained during the bending of the display module DM. In addition, the protection layer may prevent foreign substances, etc. from flowing into the display module DM through the second region A2. The protection layer according to an embodiment may include a resin. Referring to FIG. 4A, the inner space may be defined between outer surfaces of the lower member LM and a portion of the rear surface D-B facing such outer surfaces at the end portion of the display device DD.

The display device DD according to an embodiment may further include a conductive film CV disposed in the third region A3. The conductive film CV may cover a driving chip DIC to prevent static electricity introduced from the outside from damaging the driving chip DIC, and prevent foreign substances, etc. from flowing into the driving chip DIC. In addition, the conductive film CV may prevent impact from being applied to the driving chip DIC.

For a display device DD-A in FIG. 4B, differences from the display device DD in FIG. 4A will be mainly described.

The display device DD-A may include a window WM, an optical film OTF, a display module DM, and a lower member LM-A. The lower member LM-A may include a flat part AR, a protruding part SR, and a pad part PR-A. The lower member LM may be in contact with a rear surface D-B of a display panel DP.

The pad part PR-A, according to an embodiment, may include only a polymer resin, and the pigment particles, such as carbon black, included in the pad part PR described with reference to FIG. 4A, may be omitted. Accordingly, the pad part PR-A according to an embodiment may have an opaque color, whereas the pad part PR, described with reference to FIG. 4A, has the black color.

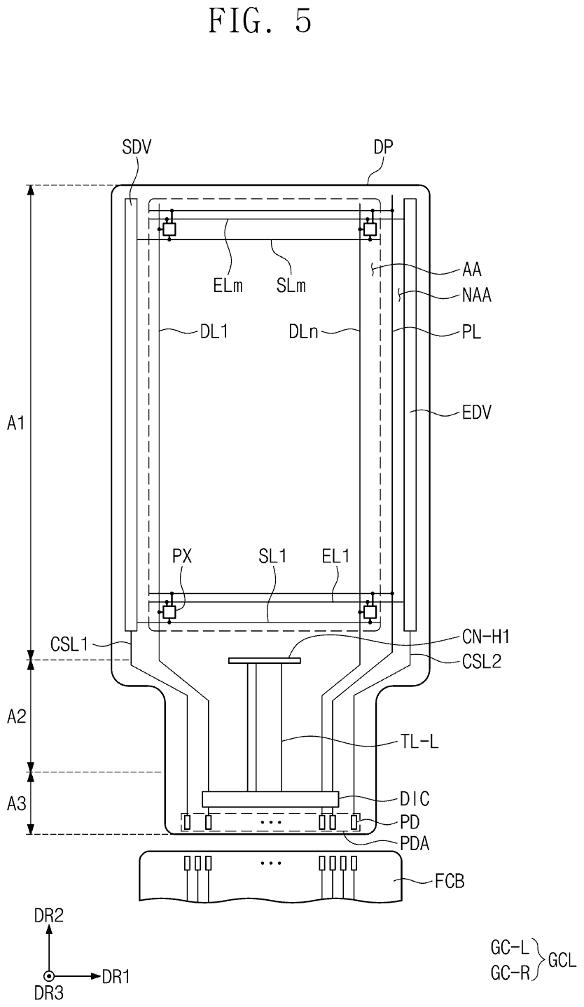

FIG. 5 is a plan view of a display panel DP according to an embodiment of the invention.

The display panel DP according to an embodiment of the invention may be divided into a first region A1, a second region A2, and a third region A3 arranged along a second direction DR2. The first to third regions A1, A2, and A3 of the display panel DP illustrated in FIG. 5 respectively correspond to the first to third regions A1, A2, and A3 of the display module DM described with reference to FIG. 2. In this specification, “one region/portion corresponding to another region/portion” means the one region/portion overlapping the other region/portion, and is not limited to the meaning of having the same area.

The display panel DP according to an embodiment may include an active region AA in which a pixel PX is disposed, and a peripheral region NAA adjacent to the active region AA. The active region AA and the peripheral region NAA respectively correspond to the active region AA and the peripheral region NAA described with reference to FIG. 2. The active region AA corresponds to a region of the first region A1 in which the pixel PX is disposed, and the peripheral region NAA is defined as the remaining region except the region in which the pixel PX is disposed.

The first region A1 may include the active region AA and a portion of the peripheral region NAA, and the second region A2 and the third region A3 may include the remaining portion of the peripheral region NAA.

The display panel DP may include a scan driver SDV, an emission driver EDV, pads PD, and a driving chip DIC in the peripheral region NAA. In this embodiment, the driving chip DIC may be a data driver.

The display panel DP may include the pixel PX provided in plural including a plurality of pixels PX, a plurality of scan lines SL1 to SLm, a plurality of data lines DL1 to DLn, a plurality of emission lines EL1 to ELm, first and second control lines CSL1 and CSL2, a power wire PL, and a plurality of pads PD. Here, ‘m’ and ‘n’ are natural numbers. The pixels PX may be connected to various signal lines among the the scan lines SL1 to SLm, the data lines DL1 to DLn, and the emission lines EL1 to ELm.

The scan lines SL1 to SLm may extend in a first direction DR1 to be connected to the scan driver SDV. The data lines DL1 to DLn may extend in a second direction DR2, and may be connected to the driving chip DIC, disposed in the third region A3, via the first region A1 and the second region A2. The emission lines EL1 to ELm may extend in the first direction DR1 to be connected to the emission driver EDV.

The power wire PL may include a portion extending in the first direction DR1 and a portion extending in the second direction DR2 (not shown). The portion extending in the first direction DR1 and the portion extending in the second direction DR2 may be disposed on different layers from each other within the display panel DP. The portion of the power wire PL extending in the second direction DR2 may extend from the first region A1 to the third region A3 via the second region A2. The power wire PL may provide a reference voltage to the pixels PX.

The first control line CSL1 may be connected to the scan driver SDV, and extend from the first region A1 to the third region A3 via the second region A2. The second control line CSL2 may be connected to the emission driver EDV, and may extend from the first region A1 to the third region A3 via the second region A2.

The pads PD may be disposed adjacent to a distal end of the display panel DP which is defined by the third region A3. Within the third region A3, the driving chip DIC, the power wire PL, the first control line CSL1, and the second control line CSL2 may be variously connected to the pads PD. A flexible circuit film FCB may overlap the display panel DP at the end portion (e.g., the distal end) of the third region A3 of the display panel DP to be disposed on the display panel DP. The flexible circuit film FCB may include circuit pads corresponding to the pads PD of the display panel DP, and may be electrically connected to the pads PD through an anisotropic conductive film (ACF).

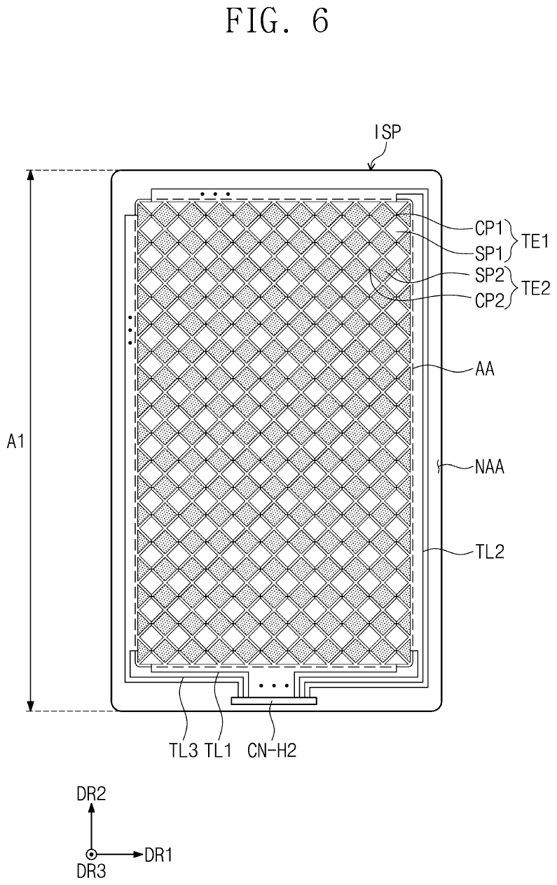

The display panel DP according to an embodiment may include a first contact hole CN-H1 defined therein at the first region A1. The display panel DP may include extended trace wires TL-L. The extended trace wires TL-L may extend to the third region A3 via the first region A1 and the second region A2. The extended trace wires TL-L may be one-to-one connected to corresponding trace wires among trace wires TL1, TL2, and TL3 (see FIG. 6), to be described later, through the first contact hole CN-H1. For example, first end portions of the extended trace wires TL-L may be exposed to outside the display panel DP by or at the first contact hole CN-H1. The extended trace wires TL-L may be connected to the trace wires TL1, TL2, and TL3 (see FIG. 6) at the first end portions. The extended trace wires TL-L may be connected to the pads PD at second end portions of the extended trace wires TL-L which are respectively opposite to the first end portions thereof.

FIG. 5 illustrates that the extended trace wires TL-L are disposed between the data lines DL1 to DLn in the plan view, but an embodiment of the invention is not limited thereto. In an embodiment, the data lines DL1 to DLn may be disposed between the extended trace wires TL-L, and accordingly, the first contact hole CN-H1 may be provided in plurality with the data lines DL1 to DLn therebetween. However, the arrangement is not limited to any one embodiment of the invention.

FIG. 6 is a plan view of an input sensor ISP according to an embodiment of the invention.

Referring to FIG. 6, an input-sensing layer as the input sensor ISP according to an embodiment may include sensing electrodes TE1 and TE2 and trace wires TL1, TL2, and TL3. In case that the input sensor ISP is directly formed on a display panel DP through a continuous process, the sensing electrodes TE1 and TE2 may be formed only in an active region AA overlapping a first region Al of the display panel DP.

The input sensor ISP may acquire information on an external input through changes in (electrical) capacitance between first sensing electrodes TE1 and second sensing electrodes TE2. The first sensing electrodes TE1 are arranged along a first direction DR1, and each of the first sensing electrodes TE1 extends along a second direction DR2. The first sensing electrodes TE1 may each include first sensing patterns SP1 and first connection patterns CP1.

The first sensing patterns SP1 are disposed in the active region AA. The first sensing patterns SP1 included in a same one first sensing electrode TE1 may be arranged along a second direction DR2. The first sensing patterns SP1 may each have a diamond shape. However, this is exemplarily illustrated, the first sensing patterns SP1 may have various planar shapes, and are not limited to any one embodiment of the invention.

The first connection pattern CP1 is disposed in the active region AA. The first connection pattern CP1 may be disposed between adjacent first sensing patterns SP1 along the second direction DR2. The first connection pattern CP1 and the first sensing pattern SP1 may be disposed on different layers from each other within the input sensor ISP, and may thus be connected to each other through a contact hole.

The second sensing electrodes TE2 are arranged along the second direction DR2, and each of the second sensing electrodes TE2 extends along the first direction DR1. The second sensing electrodes TE2 may each include second sensing patterns SP2 and second connection patterns CP2.

The second sensing patterns SP2 may be spaced apart from the first sensing patterns SP1. The first sensing patterns SP1 and the second sensing patterns SP2 may not be in contact with each other, and may thus transmit/receive electrical signals independently of each other.

The second sensing patterns SP2 are disposed in the active region AA. The second sensing patterns SP2 included in a same one second sensing electrode TE2 may be arranged along the first direction DR1. The second sensing patterns SP2 may have the same planar shape as that of the first sensing patterns SP1. For example, the second sensing patterns SP2 may each have a diamond planar shape. However, this is exemplarily illustrated, the second sensing patterns SP2 may have various shapes, and are not limited to any one embodiment of the invention.

The second connection pattern CP2 may be disposed between the adjacent second sensing patterns SP2 along the first direction DR1 and/or the second direction DR2. Substantially, the second sensing patterns SP2 and the second connection patterns CP2 included in one second sensing electrode TE2 may be formed in an integrated shape or integrated pattern. Here, the second sensing patterns SP2 and the second connection patterns CP2 may be in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto.

According to an embodiment, the first sensing patterns SP1, the second sensing patterns SP2, and the second connection patterns CP2 are disposed on (or in) the same layer, and the first connection patterns CP1 may be disposed on (or in) a different layer. The first sensing patterns SP1, the second sensing patterns SP2, and the second connection patterns CP2 may be provided as a plurality of mesh lines extending in a diagonal direction relative to each of the first direction DR1 and the second direction DR2. Mesh lines may indicate a solid portion of a material of the same layer forming the first sensing patterns SP1, the second sensing patterns SP2, and the second connection patterns CP2. The solid (line) portions may be spaced apart from each other to define an opening or gap therebetween, and the solid portions together with the openings/gaps may define a mesh shape along the plan view.

The trace wires TL1, TL2, and TL3 are disposed in a peripheral region NAA of the input sensor ISP. The trace wires TL1, TL2, and TL3 may include first trace wires TL1, second trace wires TL2, and third trace wires TL3.

The first trace wires TL1 are respectively connected to the first sensing electrodes TE1 at first ends of the first trace wires TL1. In this embodiment, the first trace wires TL1 are respectively connected to the first sensing electrodes TE1 at lower end portions among opposing end portions of the first sensing electrodes TE1. The second trace wires TL2 are respectively connected to the first sensing electrodes TE1 at upper end portions among the opposing end portions of the first sensing electrodes TE1. According to an embodiment of the invention, one first sensing electrode TE1 may be connected to the first trace wire TL1 and the second trace wire TL2. Accordingly, for the first sensing electrodes TE1, each of which has a relatively larger length (e.g., a major dimension along the second direction DR2) than that of each of the second sensing electrodes TE2 (e.g., having a major dimension along the first direction DR1), sensitivity for sensing an externa input according to region may be maintained uniformly.

In the input sensor ISP according to an embodiment of the invention, any one among the first trace wires TL1 and the second trace wires TL2 may also be omitted, and the input sensor ISP is not limited to any one embodiment of the invention.

The third trace wires TL3 are respectively connected to the second sensing electrodes TE2 at first ends of the third trace wires TL3. In this embodiment, the third trace wires TL3 are respectively connected to the second sensing electrodes TE2 at left-end portions among opposing end portions of the second sensing electrodes TE2.

In the input sensor ISP, a second contact hole CN-H2 may be defined by passing through one or more layer of the input sensor ISP such as through at least any one of insulation layers included in the input sensor ISP. The second contact hole CN-H2 may overlap the first contact hole CN-H1 defined in the first region A1 of the display panel DP.

The second end portion of each of the trace wires TL1, TL2, and TL3 may be disposed in the second contact hole CN-H2. The second end portions of the trace wires TL1, TL2, and TL3 disposed in the second contact hole CN-H2 may be respectively connected to ends of the extended trace wires TL-L (see FIG. 5). The second end portions of the trace wires TL1, TL2, and TL3 may be exposed to outside the input sensor ISP by or at the second contact hole CN-H2. The trace wires TL1, TL2, and TL3 of the input sensor ISP may be connected to the display panel DP at the pads PD (see FIG. 5) through the extended trace wires TL-L of the display panel DP (see FIG. 5).

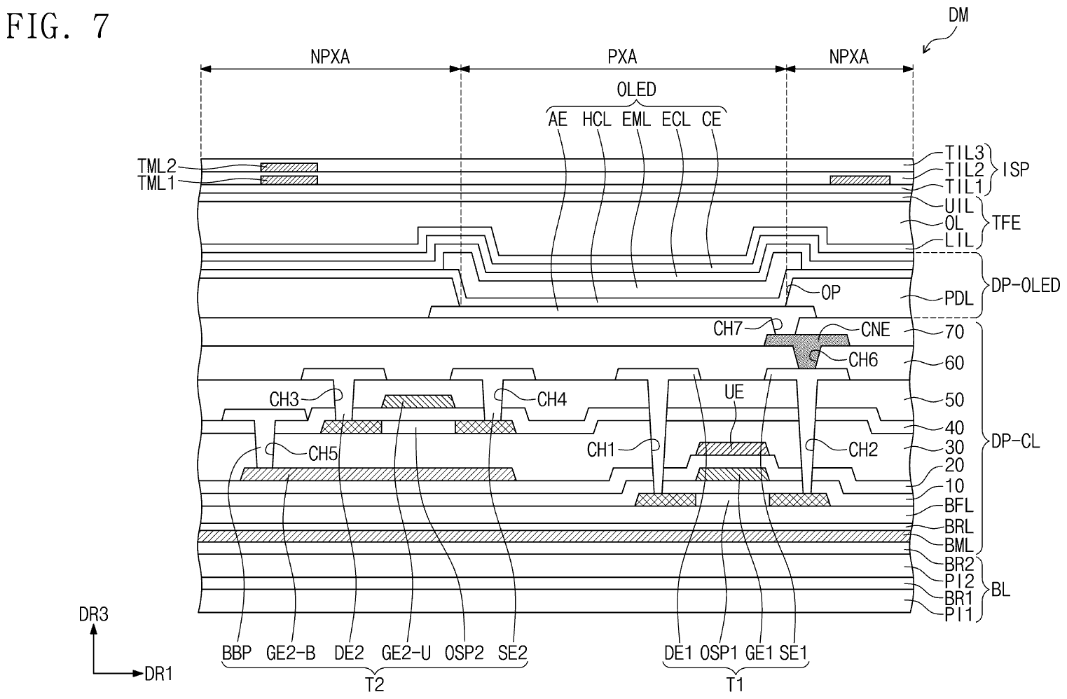

FIG. 7 is an enlarged cross-sectional view of a display module DM according to an embodiment of the invention.

FIG. 7 illustrates a cross section corresponding to a first transistor T1, a second transistor T2, and a light-emitting element OLED as a partial configuration of the pixel PX of the display area (see FIG. 5).

A display panel DP may include a base layer BL, a circuit element layer DP-CL disposed on the base layer, a display element layer DP-OLED, and an encapsulation layer TFE. The display panel DP may further include functional layers (not shown) such as an anti-reflection layer, and a refractive index control layer. The circuit element layer DP-CL includes at least a plurality of insulation layers and a circuit element. As follows, the insulation layers may include an organic layer and/or an inorganic layer.

The circuit element of the circuit element layer DP-CL includes a signal line, a driving circuit of a pixel PX, etc. The circuit element layer DP-CL may be formed through a process of forming an insulation material layer, a semiconductor material layer, and a conductive material layer by coating, deposition, etc., and through a process of patterning the insulation material layer, the semiconductor material layer, and the conductive material layer by a photolithography process. The display element layer DP-OLED may include the light-emitting element OLED and a pixel-defining film PDL. The circuit element layer DP-CL may be connected to the display element layer DP-OLED to generate light, provide the image IM, etc.

The base layer BL may include a synthetic resin film. The synthetic resin layer may include a thermosetting resin. In particular, the synthetic resin layer may be a polyimide-based resin layer, and the material is not particularly limited. The synthetic resin layer may include at least one of an acrylate-based resin, a methacrylate-based resin, polyisoprene, a vinyl-based resin, an epoxy-based resin, a urethane-based resin, a cellulose-based resin, a siloxane-based resin, a polyamide-based resin, and a perylene-based resin. In addition, the base layer may include a glass substrate, a metal substrate, an organic/inorganic composite material substrate, or the like.

The base layer BL according to an embodiment may include a first base layer PI1, a first cover layer BR1, a second base layer PI2, and a second cover layer BR2 which are stacked in sequence along a third direction DR3.

The first base layer PI1 may be disposed on the lowest side. The first base layer PI1 may include an organic material. For example, the first base layer PI1 may include any one among polyimide (PI), polyethylene naphthalate (PEN), polyethylene terephthalate (PET), polyarylate, polycarbonate (PC), polyetherimide (PEI), and polyether sulfone (PES).

The first cover layer BR1 may be disposed on the first base layer PI1. The first cover layer BR1 may include an inorganic material. For example, the first cover layer BR1 may include at least one of silicon oxide, silicon oxynitride, aluminum oxide, titanium oxide, silicon nitride, zirconium oxide, hafnium oxide and amorphous silicon.

The second base layer PI2 may be disposed on the first cover layer BR1. The second base layer PI2 may include an organic material. The organic material included in the second base layer PI2 may be the same as the organic material included in the first base layer PI1.

The second cover layer BR2 may be disposed on the second base layer PI2. The second cover layer BR2 may include an inorganic material. The inorganic material included in the second cover layer BR2 may be the same as the inorganic material included in the first cover layer BR1.

A light-blocking pattern BML may be disposed on the second cover layer BR2. The light-blocking pattern BML may prevent electrical potential, due to a polarization phenomenon, from affecting the first transistor T1. In addition, the light-blocking pattern BML may block external light from reaching the first transistor T1. According to an embodiment of the invention, the light-blocking pattern BML may also be a floating electrode in a form of being (electrically) isolated from other electrodes or wires. The light-blocking pattern BML may include molybdenum.

A barrier layer BRL may be disposed on the light-blocking pattern BML. The barrier layer BRL prevents foreign substances from entering from the outside. The barrier layer BRL may include a silicon oxide layer and a silicon nitride layer. These may each be provided in plurality, and the silicon oxide layers and the silicon nitride layers may be alternately stacked.

A buffer layer BFL may be disposed on the barrier layer BRL. The buffer layer BFL may improve bonding forces between the base layer BL and respective conductive patterns or between the base layer BL and respective semiconductor patterns. The buffer layer BFL may include silicon oxide layers and silicon nitride layers. The silicon oxide layers and the silicon nitride layers may be alternately stacked.

A first semiconductor pattern OSP1 of a first semiconductor material layer is disposed on the buffer layer BFL. The first semiconductor pattern OSP1 may include a silicon semiconductor material. The first semiconductor pattern OSP1 may be a polysilicon semiconductor. However, an embodiment of the invention is not limited thereto, and the first semiconductor pattern OSP1 may also include amorphous silicon.

The first semiconductor pattern OSP1 may include an input region (or first portion), an output region (or second portion), and a channel region (or third portion) defined between the input region and the output region in a direction along the first semiconductor material layer. The channel region of the first semiconductor pattern OSP1 may be defined corresponding to a first control electrode GE1 to be described later. The input region and the output region are doped with dopants, and thus have relatively higher (electrical) conductivity than the channel region. The input region and the output region may each be doped with an N- type dopant. In this embodiment, an N-type first transistor T1 is exemplarily illustrated, but the first transistor T1 may also be a P-type transistor.

A first insulation layer 10 is disposed on the buffer layer BFL. The first insulation layer 10 overlaps a plurality of pixels PX (see FIG. 2) in common, and covers the first semiconductor pattern OSP1. The first insulation layer 10 may be an inorganic layer and/or organic layer, and may have a single-layer or multi-layer structure. The first insulation layer 10 may include at least one of aluminum oxide, titanium oxide, silicon oxide, silicon oxynitride, zirconium oxide and hafnium oxide. In this embodiment, the first insulation layer 10 may be a single-layer silicon oxide layer (e.g., a monolayer of silicon oxide).

The first control electrode GE1 is disposed on the first insulation layer 10. The first control electrode GE1 overlaps the channel region of the first semiconductor pattern OSP1.

A second insulation layer 20 covering the first control electrode GE1 is disposed on the first insulation layer 10. The second insulation layer 20 overlaps the plurality of pixels PX (see FIG. 1) in common. The second insulation layer 20 may be an inorganic layer and/or organic layer, and may have a single-layer or multi-layer structure. The second insulation layer 20 may include at least one of aluminum oxide, titanium oxide, silicon oxide, silicon oxynitride, zirconium oxide and hafnium oxide. In this embodiment, the second insulation layer 20 may be a single-layer silicon oxide layer.

An upper electrode UE may further be disposed on the second insulation layer 20. The upper electrode UE may overlap the first control electrode GE1.

A lower control electrode GE2-B of the second transistor T2 may further be disposed on the second insulation layer 20. The lower control electrode GE2-B may overlap a second semiconductor pattern OSP2. The lower control electrode GE2-B may form a dual gate together with an upper control electrode GE2-U.

A third insulation layer 30 covering the upper electrode UE and the lower control electrode GE2-B is disposed on the second insulation layer 20. The third insulation layer 30 may be an inorganic layer and/or organic layer, and may have a single-layer or multi- layer structure. The third insulation layer 30 may include at least one of aluminum oxide, titanium oxide, silicon oxide, silicon oxynitride, zirconium oxide and hafnium oxide. In this embodiment, the third insulation layer 30 may be a single-layer silicon oxide layer.

The second semiconductor pattern OSP2 of a second semiconductor material layer is disposed on the third insulation layer 30. The second semiconductor pattern OSP2 may include an oxide semiconductor. The second semiconductor pattern OSP2 may include a crystalline or amorphous oxide semiconductor. For example, the oxide semiconductor may include a metal oxide of zinc (Zn), indium (In), gallium (Ga), tin (Sn), titanium (Ti), etc., or a combination of metal such as zinc (Zn), indium (In), gallium (Ga), tin (Sn), titanium (Ti), etc. and the oxide thereof. The oxide semiconductor may include indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), etc.

The second semiconductor pattern OSP2 may include an input region (or first portion), an output region (or second portion), and a channel region (or third portion) defined between the input region and the output region. The input region and the output region may include impurities. The channel region of the second semiconductor pattern OSP2 may be defined corresponding to the upper control electrode GE2-U to be described later.

The impurities of the second semiconductor pattern OSP2 may be reduced metal materials. The input region and the output region may include the metal materials reduced from the metal oxide composing the channel region. Accordingly, the second transistor T2 may function as a switching element capable of reducing leakage current and thus having improved on and off characteristics.

A fourth insulation layer 40 covering the second semiconductor pattern OSP2 is disposed on the third insulation layer 30. The fourth insulation layer 40 may be an inorganic layer and/or organic layer, and may have a single-layer or multi-layer structure. The fourth insulation layer 40 may include at least one of aluminum oxide, titanium oxide, silicon oxide, silicon oxynitride, zirconium oxide and hafnium oxide.

The upper control electrode GE2-U is disposed on the fourth insulation layer 40. The upper control electrode GE2-U overlaps the second semiconductor pattern OSP2.

A fifth insulation layer 50 covering the upper control electrode GE2-U is disposed on the fourth insulation layer 40. The fifth insulation layer 50 may be an inorganic layer and/or organic layer, and may have a single-layer or multi-layer structure. The fifth insulation layer 50 may include at least one of aluminum oxide, titanium oxide, silicon oxide, silicon oxynitride, zirconium oxide and hafnium oxide.

A first input electrode DE1, a first output electrode SE1, a second input electrode DE2, and a second output electrode SE2 are disposed on the fifth insulation layer 50. The first input electrode DE1 and the first output electrode SE1 are connected to the first semiconductor pattern OSP1 through a first contact hole CH1 and a second contact hole CH2 respectively exposing the input region and the output region of the first semiconductor pattern OSP1. The first contact hole CHI and the second contact hole CH2 pass through the first insulation layer 10 to the fifth insulation layer 50.

A second input electrode DE2 and a second output electrode SE2 are connected to the second semiconductor pattern OSP2 through a third contact hole CH3 and a fourth contact hole CH4 respectively exposing the input region and the output region of the second semiconductor pattern OSP2. The third contact hole CH3 and the fourth contact hole CH4 pass through the fifth insulation layer 50.

The display panel DP according to an embodiment may further include a control bridge pattern BBP disposed on the fourth insulation layer 40. The control bridge pattern BBP may be ramified from a portion of the upper control electrode GE2-U. That is, control bridge pattern BBP and the upper control electrode GE2-U may be portions of a same material layer. The control bridge pattern BBP may be connected to the lower control electrode GE2-B through a fifth contact hole CH5. The fifth contact hole CH5 passes through the third insulation layer 30 and the fourth insulation layer 40.

A sixth insulation layer 60 covering the first input electrode DE1, the first output electrode SE1, the second input electrode DE2, and the second output electrode SE2 is disposed on the fifth insulation layer 50. The sixth insulation layer 60 may be an organic layer, and may have a single-layer or multi-layer structure.

A connection electrode CNE is disposed on the sixth insulation layer 60. The connection electrode CNE may be connected to the first output electrode SE1 through a sixth contact hole CH6 passing through the sixth insulation layer 60.

A seventh insulation layer 70 (or passivation layer) covering the connection electrode CNE is disposed on the sixth insulation layer 60. The seventh insulation layer 70 may be an organic layer, and may have a single-layer or multi-layer structure.

In this embodiment, the sixth insulation layer 60 and the seventh insulation layer 70 may each be a single-layer polyimide-based resin layer. An embodiment of the invention is not limited thereto, and the sixth insulation layer 60 and the seventh insulation layer 70 may include at least one of an acrylate-based resin, a methacrylate-based resin, polyisoprene, a vinyl-based resin, an epoxy-based resin, a urethane-based resin, a cellulose-based resin, a siloxane-based resin, a polyamide-based resin, and a perylene-based resin.

The light-emitting element OLED is disposed on the seventh insulation layer 70. An anode AE of the light-emitting element OLED is disposed on the seventh insulation layer 70. The anode AE is connected to the connection electrode CNE through a seventh contact hole CH7 passing through the seventh insulation layer 70. The pixel-defining film PDL is disposed on the seventh insulation layer 70.

An opening OP of the pixel-defining film PDL exposes at least a portion of the anode AE. The opening OP of the pixel-defining film PDL may define a light-emitting region PXA of a pixel PX. For example, the plurality of pixels PX (see FIG. 2) may be disposed on a flat surface of the display panel DP with a certain rule or arrangement. The region (or planar area) in which the plurality of pixels PX are disposed may correspond to the active region AA described with reference to FIG. 5. The active region AA (or the display area) may include the light-emitting regions PXA and a non-light-emitting region NPXA which is adjacent to the light-emitting regions PXA. The non-light-emitting region NPXA may surround the light-emitting regions PXA.

A hole control layer HCL may be disposed in the light-emitting regions PXA and the non-light-emitting region NPXA in common. A common layer, such as the hole control layer HCL, may be formed across the plurality of pixels PX (see FIG. 2) in common. The hole control layer HCL may include a hole transport layer and a hole injection layer.

An organic light-emitting layer EML is disposed on the hole control layer HCL. The organic light-emitting layer EML may be disposed only in a region corresponding to the opening OP. The organic light-emitting layer EML may be formed separately for each of the plurality of pixels PX (see FIG. 2). Here, the organic light-emitting layer EML may be a discrete pattern in a plan view, such as having a planar shape which is separated from other discrete patterns of a light emitting layer including plural organic light-emitting layers EML.

In this embodiment, the patterned organic light-emitting layer EML is exemplarily illustrated, but the organic light-emitting layer EML may be disposed across the plurality of pixels PX in common. At this time, the organic light-emitting layer EML may generate the white light. In addition, the organic light-emitting layer EML may have a multi-layer structure.

An electron control layer ECL is disposed on the organic light-emitting layer EML. The electron control layer ECL may include an electron transport layer and an electron injection layer. A cathode CE is disposed on the electron control layer ECL. The electron control layer ECL and the cathode CE are disposed across the plurality of pixels PX (see FIG. 2) in common.

The encapsulation layer TFE is disposed on the cathode CE. The encapsulation layer TFE is disposed across the plurality of pixels PX in common. In this embodiment, the encapsulation layer TFE directly covers the cathode CE. The encapsulation layer TFE may cover the light-emitting element OLED. The encapsulation layer TFE may include two inorganic encapsulation layers LIL and UIL and an organic encapsulation layer OL disposed therebetween. According to an embodiment of the invention, the encapsulation layer TFE may include a plurality of inorganic layers and a plurality of organic layers alternately stacked.

The inorganic encapsulation layers LIL and UIL protect the light-emitting element OLED from moisture/oxygen, and the organic encapsulation layer OL protects the light-emitting element OLED from foreign substances such as dust particles. The inorganic encapsulation layers LIL and UIL may include a silicon nitride layer, a silicon oxynitride layer, a silicon oxide layer, a titanium oxide layer, an aluminum oxide layer, or the like, and are not limited particularly thereto. The organic encapsulation layer OL may include an acrylate-based organic layer, and is not limited particularly thereto.

According to this embodiment, the first transistor T1 may include the silicon semiconductor, and particularly, the polysilicon semiconductor, and may thus have high electron mobility. The second transistor T2 includes the oxide semiconductor, so that the leakage current is reduced. Therefore, a driving voltage of the pixel PX (see FIG. 2) is decreased and malfunctioning is prevented.

An input sensor ISP may be directly disposed on the display panel DP. The input sensor ISP may include sensing insulation layers TIL1, TIL2, and TIL3, and at least one conductive layer such as including conductive layers TML1 and TML2. The sensing insulation layers TIL1, TIL2, and TIL3 may include any one among an inorganic material and an organic material.

A first sensing insulation layer TIL1 may be directly disposed on the second inorganic layer UIL of the encapsulation layer TFE. A first conductive layer TML1 is disposed on the first sensing insulation layer TIL1. A second sensing insulation layer TIL2 may be disposed on the first sensing insulation layer TIL1, and cover the first conductive layer TML1. A second conductive layer TML2 is disposed on the second sensing insulation layer TIL2. A third sensing insulation layer TIL3 may be disposed on the second sensing insulation layer TIL2 and cover the second conductive layer TML2. However, an embodiment of the invention is not limited thereto, and the first sensing insulation layer TIL1 may be omitted, and the first conductive layer TML1 may be directly disposed on the second inorganic layer UIL, and the structure is not limited to any one embodiment of the invention.

According to an embodiment of the invention, the first and second sensing insulation layers TIL1 and TIL2 may include inorganic materials, and the third sensing insulation layer TIL3 may include an organic material.

First connection patterns CP1 of the sensing electrodes TE1 and TE2, described with reference to FIG. 6, may be included in the first conductive layer TML1. First sensing patterns SP1, second sensing patterns SP2, and second connection patterns CP2 may be included in the second conductive layer TML2. Therefore, the adjacent first sensing patterns SP1 may be connected to the first connection pattern CP1 in a different layer from the first sensing patterns SP1, through a contact hole defined in the second sensing insulation layer TIL2.

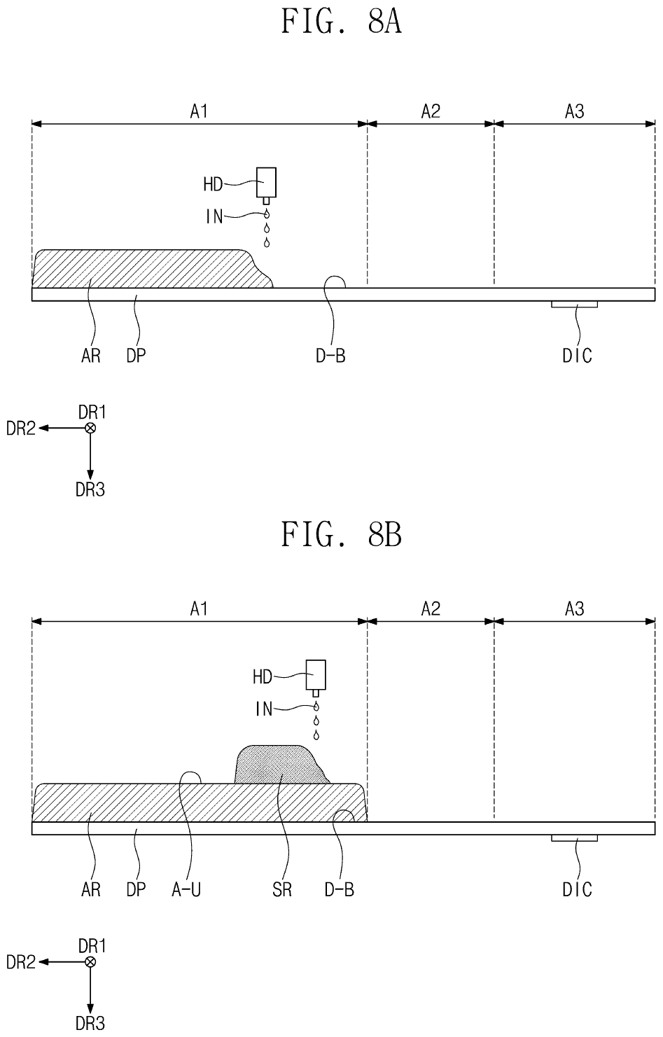

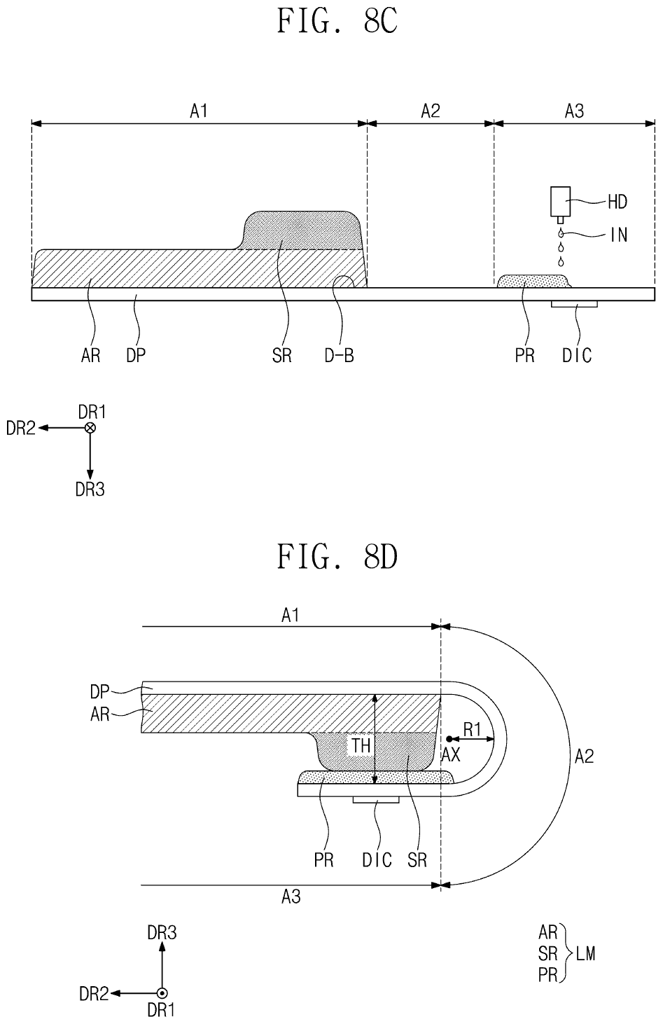

FIGS. 8A to 8D are cross-sectional views illustrating structure in a method of manufacturing (or providing) a display device DD according to an embodiment of the invention. Hereinafter, referring to FIGS. 8A to 8D, manufacturing a lower member LM to be formed (or provided) on a rear surface D-B of a display panel DP will be described. The manufacturing of the lower member LM, to be described below, may be performed through an inkjet process or a dispenser process, and is not limited to any one embodiment of the invention.

Referring to FIG. 8A, the manufacturing method of the display device DD may include forming a flat part AR on the rear surface D-B of a preliminary form of the display panel DP. A preliminary display panel may include the driving chip DIC on a front surface of the display panel DP which is opposite to the rear surface D-B thereof. The flat part AR may be formed on the rear surface D-B to overlap the entire surface (or planar area) of a first region A1.

In the manufacturing method of the display device DD, the flat part AR may be formed by spraying a material such as ink IN onto the rear surface D-B of the display panel DP through a nozzle HD. The ink IN may be an ink material in which a polymer resin contains carbon black. In addition, the ink IN may include at least one of graphite, copper (Cu), aluminum (Al), carbon nanotube (CNT) and graphene for a heat-dissipating function. According to an embodiment of the invention, the optical density of the material contained in the ink IN may be about 3 to about 5, the thermal conductivity may be about 20 w/mk to about 100 W/mk, and the storage modulus may be about 0.01 MPa to about 1 MPA.

The flat part AR may be formed on the rear surface D-B of the display panel DP at a planar area thereof overlapping the first region A1. The thickness of the flat part AR may be 100 μm or more and 300 μm or less, based on the rear surface D-B of the display panel DP. After the flat part AR is formed, a curing process may be performed. Here, the flat part AR may be a cured pattern of material. The flat pattern AR may have an end surface which is closest to the second region A2.

After this, referring to FIG. 8B, the manufacturing method of the display device DD may include forming a protruding part SR on the flat part AR. The protruding part SR may be formed on the flat part AR to overlap the first region A1 at a position adjacent (or closest) to a boundary between the first region A1 and a second region A2. The protruding part SR may expose a portion of an upper surface A-U of the flat part AR. After the protruding part SR is formed, a curing process may be performed. Here, the protruding part SR may be a cured pattern of material. The protruding part SR may have an end surface which is closest to the second region A2. That is, the lower member LM may have a side surface which is closest to the second region A2 and formed by end surfaces of the flat part AR and the protruding part SR together with each other.

After this, referring to FIG. 8C, the manufacturing method of the display device DD may include forming a pad part PR on the rear surface D-B of the display panel DP. The pad part PR may be formed on the rear surface D-B of the display panel DP overlapping a third region A3. An exposed portion of the rear surface D-B may be between the flat part AR and the pad part PR. After the pad part PR is formed, a curing process may be performed. Here, the pad part PR may be a cured pattern of material. The lower member LM including cured patterns as the flat part AR, the protruding part SR and the pad part PR directly on the display panel DP may be completed.

The lower member LM as an electromagnetic wave-shielding/light-blocking/heat-dissipating and/or cushioning functional (protection) layer includes patterns which are disconnected from each other at the second region A2 (e.g., the bending region) of the display device DD. The pad part PR may be coplanar with the flat part AR. That is, the display panel DP which is unbent or flat includes the pad part PR coplanar with the flat part AR.

After this, referring to FIG. 8D, the manufacturing method of the display device DD may include bending the display panel DP at the second region A2 of the display panel DP (e.g., a bending region of the display panel DP). When the second region A2 is bent, the pad part PR and the protruding part SR may face each other and come into contact with each other along a third direction DR3. According to an embodiment of the invention, when a distance from a bending axis AX to the second region A2 of the rear surface D-B of the display panel DP is defined as a radius of curvature R1, double the radius of curvature R1 may be equal to the total thickness TH of the flat part AR, the protruding part SR, and the pad part PR. Each of the parts may contribute a thickness portion of the total thickness TH. According to this embodiment, the protruding part SR may have a reversed trapezoidal shape on a cross section.

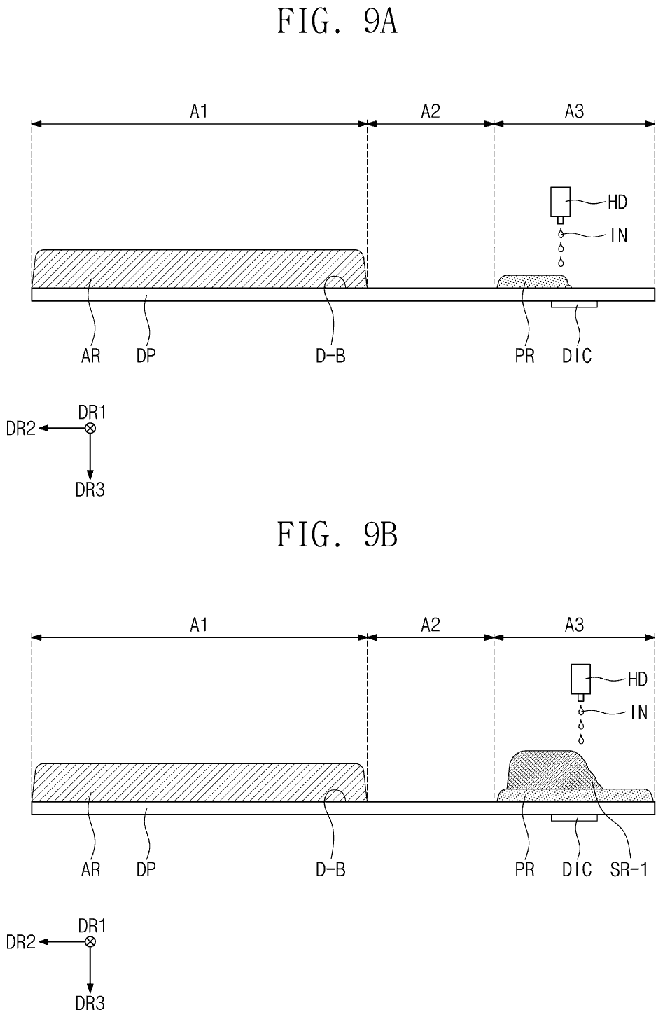

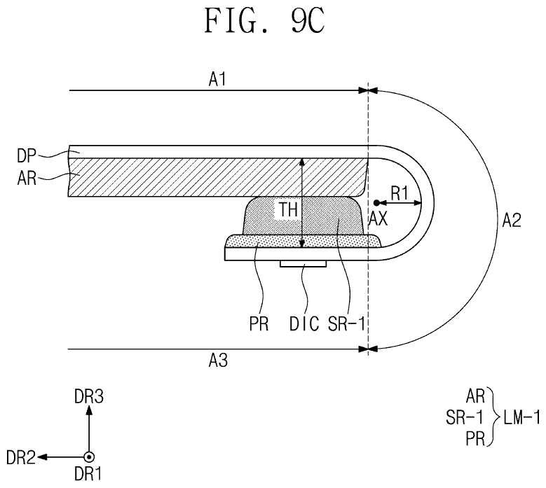

FIGS. 9A to 9C are cross-sectional views illustrating a manufacturing method of a display device DD according to an embodiment of the invention. Manufacturing a lower member LM-1 according to this embodiment is the same as the process of manufacturing the flat part AR in FIG. 8A, and the following process will be described.

Referring to FIG. 9A, the manufacturing method of the display device DD may include, after the manufacturing of the flat part AR, forming a pad part PR on a rear surface D-B of a display panel DP at a position spaced apart from the side surface of the flat part AR which is closest to the second region A2. The pad part PR may be formed on the rear surface D-B of the display panel DP overlapping a planar area of the third region A3. After the pad part PR is formed, a curing process may be performed.

After this, referring to FIG. 9B, the manufacturing method of the display device DD may include forming a protruding part SR-1 on the pad part PR. The protruding part SR-1 may be formed on the pad part PR overlapping the third region A3. The protruding part SR-1 may cover a portion of a planar area of an upper surface of the pad part PR. After the protruding part SR-1 is formed, a curing process may be performed. That is, the display panel DP which is unbent or flat includes the protruding part SR and the pad part PR coplanar with the flat part AR.

After this, referring to FIG. 9C, the manufacturing method of the display device DD may include bending the display panel DP at a second region A2 of the display panel DP. When the second region A2 is bent, the flat part AR and the protruding part SR-1 may face each other and come into contact with each other along a third direction DR3. Here, the display panel DP which is bent at the second region A2 includes the flat part AR and the protruding part SR-1 in contact with each other.

According to an embodiment of the invention, when a distance from a bending axis AX to the second region A2 of the rear surface D-B of the display panel DP is defined as a radius of curvature R1, double the radius of curvature R1 may be equal to the total thickness TH of the flat part AR, the protruding part SR-1, and the pad part PR. According to this embodiment, the protruding part SR-1 may have a trapezoidal shape on a cross section.

According to an embodiment of the invention, in a display device DD including a display panel DP having a portion of which is bendable, by simplifying functional layers of a lower member LM disposed under the display panel DP, the cost for a manufacturing method of the display device DD may be reduced, and the process may be simplified.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention should not be limited to the contents described in the detailed description of the specification, but should be defined by the claims.

What is claimed is:

1. A display device comprising:
a display panel including:
a front surface and a rear surface opposite to each other,
a first region in which pixels are disposed,
a second region which is bendable with respect to a bending axis extending along a first direction,
a boundary between the first region and the second region, and
a third region which is spaced apart from the first region along a second direction crossing the first direction with the second region therebetween, the third region including a driving chip on the front surface and pads which are adjacent to the driving chip; and
a lower member including:
a flat part which overlaps an entirety of the first region and is in contact with the rear surface of the display panel at the first region,
a protruding part which is on the flat part and adjacent to the boundary between the first region and the second region, and
a pad part which is disconnected from the flat part and the protruding part, overlaps the third region and is in contact with the rear surface of the display panel at the third region,
wherein the display panel which is bent at the second region includes the protruding part and the pad part in contact with each other.

2. The display device of claim 1, wherein the protruding part is on an upper surface of the flat part and exposes a portion of the upper surface of the flat part.

3. The display device of claim 1, wherein the flat part has a first thickness, the protruding part has a second thickness smaller than the first thickness, and the pad part has a third thickness smaller than the second thickness.

4. The display device of claim 3, wherein the first thickness is about 100micrometers or more and about 300 micrometers or less, the second thickness is about 50 micrometers or more and about 200 micrometers or less, and the third thickness is about 50 micrometers or more and about 150 micrometers or less.

5. The display device of claim 1, wherein the flat part, the protruding part and the pad part each comprise a polymer resin and carbon black.

6. The display device of claim 5, wherein the flat part, the protruding part, and the pad part further comprise at least one of graphite, copper, aluminum, carbon nanotube and graphene.

7. The display device of claim 1, wherein
the flat part and the protruding part each comprise a polymer resin and carbon black, and
the pad part comprises only the polymer resin.

8. The display device of claim 1, wherein the lower member has an optical density of about 3 to about 5.

9. The display device of claim 1, wherein the lower member has a thermal conductivity of about 20 watts per meter Kelvin to about 100 watts per meter Kelvin.

10. The display device of claim 1, wherein the lower member has a storage modulus of about 0.01 megapascal to about 1 megapascal.

11. The display device of claim 1, further comprising an input sensor directly on the display panel.

12. The display device of claim 1, further comprising an optical film facing the first region of the display panel.

13. The display device of claim 12, further comprising a window facing the display panel with the optical film therebetween.

14. The display device of claim 1, further comprising a bending cover layer which covers the front surface of the display panel at the second region of the display panel.

15. The display device of claim 1, further comprising a flexible circuit film connected to the display panel at the pads of the display panel,
wherein the display panel which is bent at the second region further includes a portion of the flexible circuit film in contact with the flat part of the lower member.

16. The display device of claim 15, further comprising a conductive film which is on the front surface of the display panel, covers the driving chip of the display panel, and extends from the driving chip to overlap the flexible circuit film and the pads.

17. A method of providing a display device, comprising:
providing a display panel including a front surface and a rear surface opposite to each other, a first region in which pixels are disposed, a second region which is bendable with respect to a bending axis extending along a first direction, a boundary between the first region and the second region, and a third region which is spaced apart from the first region along a second direction crossing the first direction with the second region therebetween, the third region including a driving chip on the front surface and pads which are adjacent to the driving chip;
providing a flat part of a functional protection layer on the rear surface of the display panel at the first region of the display panel;
providing a protruding part of the functional protection layer which is on the flat part and adjacent to the boundary between the first region and the second region of the display panel;
providing a pad part of the functional protection layer on the rear surface of the display panel at the third region of the display panel, the pad part being disconnected from the flat part and the protruding part; and
bending the display panel at the second region,
wherein the display panel which is bent at the second region includes the protruding part and the pad part in contact with each other.

18. The method of claim 17, wherein
the providing of the flat part, the protruding part and the pad part includes providing ink onto the rear surface of the display panel using an inkjet process, and
the ink includes a polymer resin and carbon black.

19. The method of claim 18, wherein the ink has an optical density of about 3 to about 5 together with a thermal conductivity of about 20 watts per meter Kelvin to about 100 watts per meter Kelvin and a storage modulus of about 0.01 megapascal to about 1 megapascal.

20. A method of providing a display device, comprising:
providing a display panel including a front surface and a rear surface opposite to each other, a first region in which pixels are disposed, a second region which is bendable with respect to a bending axis extending along a first direction, and a third region which is spaced apart from the first region along a second direction crossing the first direction with the second region therebetween, the third region including a driving chip on the front surface and pads which are adjacent to the driving chip;
providing a flat part of a functional protection layer on the rear surface of the display panel at the first region of the display panel;
providing a pad part of the functional protection layer on the rear surface of the display panel at the third region of the display panel;
providing a protruding part of the functional protection layer on the pad part, the protruding part and the pad part being disconnected from the flat part; and
bending the display panel at the second region,
wherein the display panel which is bent at the second region includes the flat part and the protruding part in contact with each other.
